(19) United States
(12) Patent Application Publication
(10) Pub. No.: US 2025/0087607 A1
(43) Pub. Date: Mar. 13, 2025

(54) SEMICONDUCTOR PACKAGE

(71) Applicant: SAMSUNG ELECTRONICS CO., LTD., Suwon-si (KR)

(72) Inventors: HYEONMIN LEE, Suwon-si (KR); Haseob Seong, Suwon-si (KR); MINSEUNG JI, Suwon-si (KR)

(21) Appl. No.: 18/773,068

(22) Filed: Jul. 15, 2024

(30) Foreign Application Priority Data
Sep. 11, 2023 (KR) 10-2023-0120612

(51) Int. Cl. H01L 23/00; H01L 23/48; H01L 23/528; H01L 25/065

(52) U.S. Cl. CPC H01L 24/08; H01L 23/481; H01L 23/5283; H01L 25/0657; H01L 2224/08145; H01L 2225/06544; H01L 2924/1431

(57) ABSTRACT

A semiconductor package includes a first semiconductor chip, a dummy die on the first semiconductor chip, second semiconductor chips stacked on the dummy die, and a dummy plate on the second semiconductor chips. Each of the first semiconductor chip, the dummy die, and the second semiconductor chips includes through-electrodes. The dummy die and the second semiconductor chip closest to the dummy die are connected to each other by direct contact of bonding pads. Adjacent ones of the second semiconductor chips are connected to each other by direct contact of bonding pads. The first semiconductor chip, the dummy die, the second semiconductor chip, and the dummy plate have a first width, a second width, a third width, and a fourth width in a horizontal direction, respectively. The fourth width is greater than the second width and the third width.

### CROSS-REFERENCE TO RELATED APPLICATIONS

This U.S. non-provisional patent application claims priority under 35 U.S.C. § 119 to Korean Patent Application No. 10-2023-0120612, filed on Sep. 11, 2023, in the Korean Intellectual Property Office, the entire contents of which are hereby incorporated by reference.

### BACKGROUND

### 1. Technical Field

Embodiments of the present disclosure relate to a semiconductor package, and more particularly, to a semiconductor package including a plurality of stacked semiconductor chips.

### 2. Background Art

High-performance electronic devices have been demanded with the development of the electronic industry. Thus, a method of disposing a plurality of semiconductor chips has been required to realize the high performance of electronic devices. Therefore, a semiconductor package including a plurality of semiconductor chips having through-electrodes and stacked in a vertical direction has been suggested.

### SUMMARY

According to embodiments of the present disclosure, a semiconductor package is provided that includes core dies and a dummy plate adhered onto an uppermost one of the core dies by a hybrid bonding method and which is capable of increasing adhesive strength between the dummy plate and the uppermost core die while increasing a thickness of the dummy plate, to improve reliability of the semiconductor package.

According to embodiments of the present disclosure, a semiconductor package is provided. The semiconductor package includes: a first semiconductor chip; a dummy die on the first semiconductor chip; second semiconductor chips stacked on the dummy die; and a dummy plate on the second semiconductor chips, wherein each of the first semiconductor chip, the dummy die, and the second semiconductor chips includes through-electrodes, wherein the dummy die and a lowermost one among the second semiconductor chips, closest to the dummy die, are connected to each other by direct contact of first bonding pads, wherein adjacent ones of the second semiconductor chips are connected to each other by direct contact of second bonding pads, wherein the first semiconductor chip, the dummy die, the second semiconductor chips and the dummy plate have a first width, a second width, a third width, and a fourth width in a horizontal direction, respectively, and wherein the fourth width is greater than the second width and the third width.

According to embodiments of the present disclosure, a semiconductor package is provided. The semiconductor package includes: a first semiconductor chip: a dummy die on the first semiconductor chip; second semiconductor chips stacked on the dummy die: a dummy plate on the second semiconductor chips; and a molding structure between the first semiconductor chip and the dummy plate, wherein each of the first semiconductor chip, the dummy die, and the second semiconductor chips includes through-electrodes, wherein the dummy die and the first semiconductor chip are connected to each other by direct contact of first bonding pads, wherein the dummy die and a lowermost one among the second semiconductor chips are connected to each other by direct contact of second bonding pads, wherein adjacent ones of the second semiconductor chips are connected to each other by direct contact of third bonding pads, wherein the dummy plate and an uppermost one among the second semiconductor chips are connected to each other by direct contact of insulating materials, and wherein the molding structure is on a top surface of the first semiconductor chip, a side surface of the dummy die, side surfaces of the second semiconductor chips, and a bottom surface of the dummy plate.

According to embodiments of the present disclosure, a semiconductor package is provided. The semiconductor package includes: a package substrate; an interposer on the package substrate; a logic chip on the interposer; and chip stack structures spaced apart from each other with the logic chip interposed therebetween. Each of the chip stack structures includes: a buffer die; a dummy die on the buffer die: core dies stacked on the dummy die; a dummy plate on the core dies; and a molding structure between the buffer die and the dummy plate, wherein each of the buffer die, the dummy die, and the core dies includes through-electrodes, wherein the dummy die and the buffer die are connected to each other by direct contact of first bonding pads, wherein the dummy die and a lowermost one among the core dies are connected to each other by direct contact of second bonding pads, wherein adjacent ones of the core dies are connected to each other by direct contact of third bonding pads, wherein the dummy plate and an uppermost one among the core dies are connected to each other by direct contact of insulating materials, wherein the molding structure is on a top surface of the buffer die, a side surface of the dummy die, side surfaces of the core dies, and a bottom surface of the dummy plate, wherein the buffer die, the dummy die, the core dies, and the dummy plate have a first width, a second width, a third width, and a fourth width in a horizontal direction, respectively, wherein the first width is substantially equal to the fourth width, and wherein the second width is substantially equal to the third width.

### BRIEF DESCRIPTION OF THE DRAWINGS

FIG. 1A is a cross-sectional view illustrating a semiconductor package according to some embodiments of the present disclosure.

FIG. 1B is a cross-sectional view conceptually illustrating top surfaces and bottom surfaces of dies of the semiconductor package of FIG. 1A.

FIG. 2 is an enlarged view of a region CU1 of FIG. 1A.

FIG. 3 is an enlarged view of a region CU2 of FIG. 1A.

FIG. 4 is a cross-sectional view illustrating a semiconductor package according to some embodiments of the present disclosure.

FIG. 5A is an enlarged view corresponding to a region CU3 of FIG. 4.

FIG. 5B is an enlarged view corresponding to the region CU3 of FIG. 4.

FIGS. 6A, 7A, 8A, and 9A are cross-sectional views illustrating a method of manufacturing a semiconductor package according to some embodiments of the present disclosure.

FIGS. 6B, 7B, 8B, and 9B are cross-sectional views conceptually illustrating top surfaces and bottom surfaces of dies of FIGS. 6A, 7A, 8A, and 9A, respectively.

FIGS. 6C and 7C are enlarged views of a region CU4 of FIG. 6A and a region CU5 of 7A, respectively.

FIG. 10 is a cross-sectional view illustrating a method of manufacturing a semiconductor package according to some embodiments of the present disclosure.

FIG. 11 is an enlarged view corresponding to a region CU6 of FIG. 10.

FIG. 12 is an enlarged view corresponding to the region CU6 of FIG. 10.

FIG. 13A is a cross-sectional view illustrating a method of manufacturing a semiconductor package according to some embodiments of the present disclosure.

FIG. 13B is a cross-sectional view conceptually illustrating top surfaces and bottom surfaces of dies of FIG. 13A.

FIG. 14 is a plan view illustrating a semiconductor package according to some embodiments of the present disclosure.

FIG. 15 is a cross-sectional view taken along a line I-I′ of FIG. 14.

### DETAILED DESCRIPTION

Example embodiments of the present disclosure will now be described more fully with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

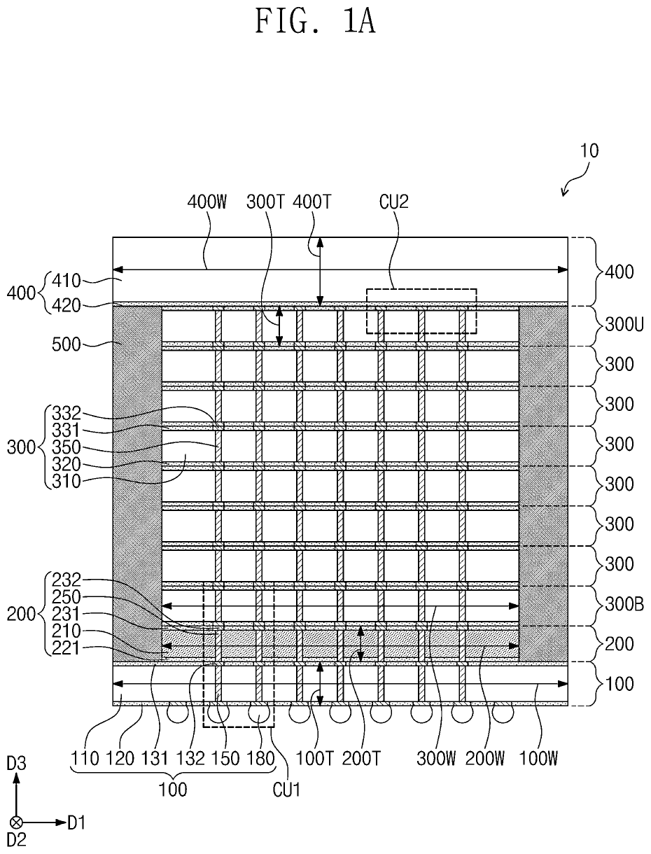

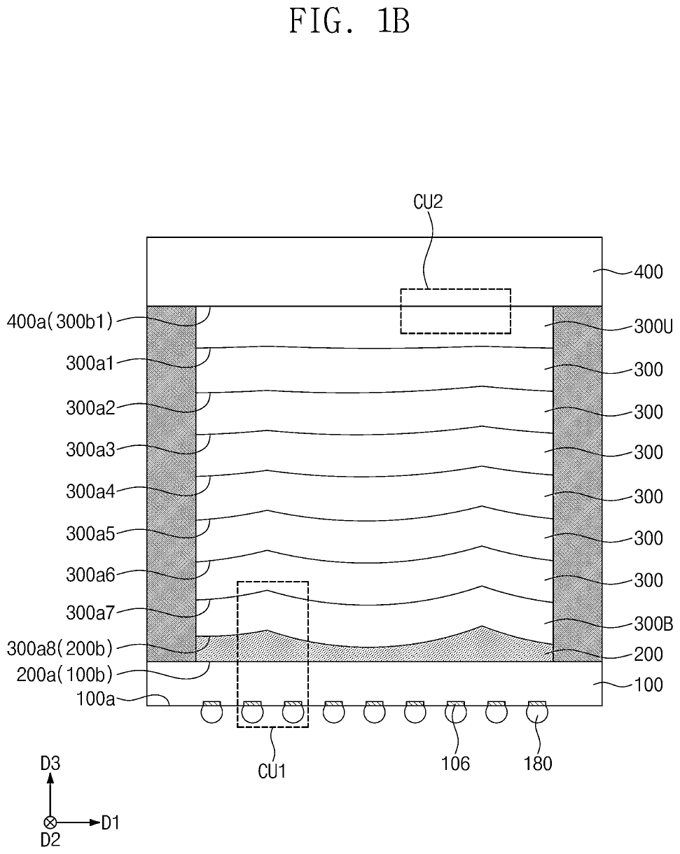

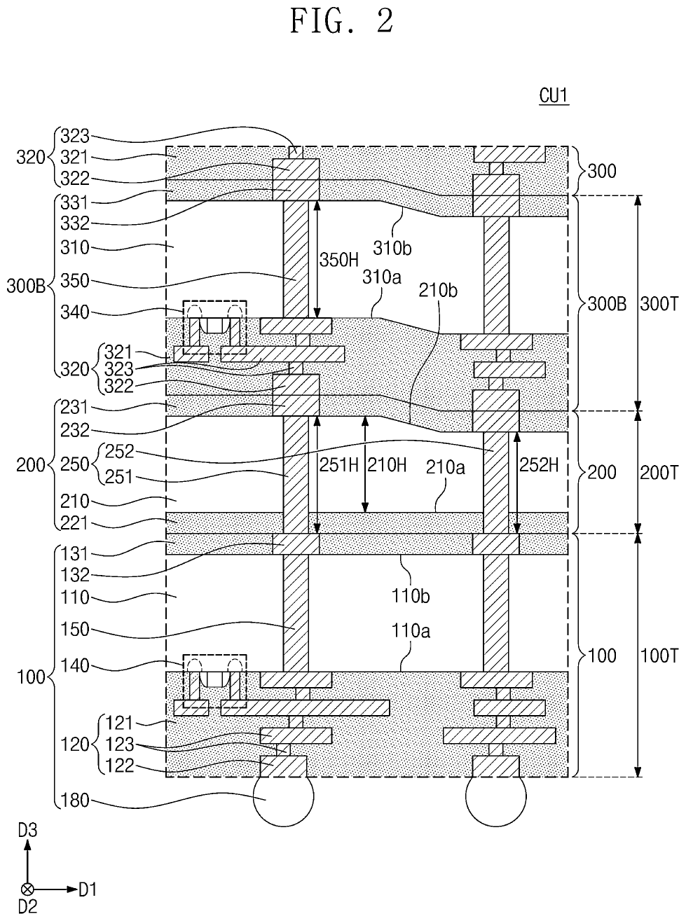

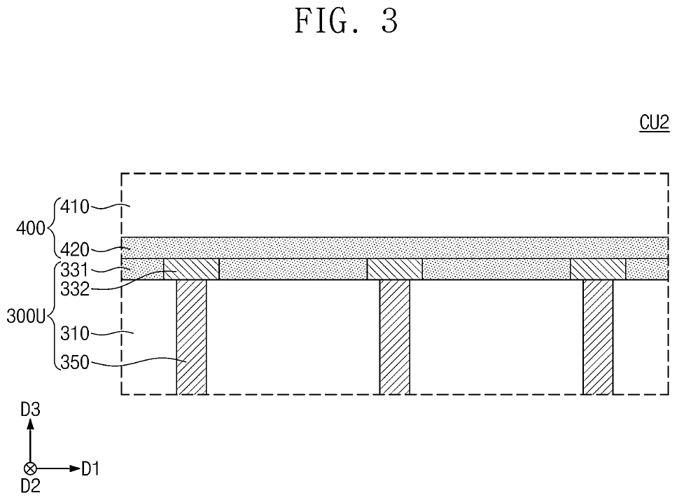

FIG. 1A is a cross-sectional view illustrating a semiconductor package according to some embodiments of the present disclosure. FIG. 1B is a cross-sectional view conceptually illustrating top surfaces and bottom surfaces of dies of the semiconductor package of FIG. 1A. FIG. 2 is an enlarged view of a region CU1 of FIG. 1A. FIG. 3 is an enlarged view of a region CU2 of FIG. 1A.

Referring to FIGS. 1A and 1B, for example, a semiconductor package 10 according to embodiments of the present disclosure may be a high bandwidth memory (HBM). In the present specification, the semiconductor package 10 may also be referred to as a chip stack structure. The semiconductor package 10 may include a first semiconductor chip 100, a dummy die 200, second semiconductor chips 300B, 300 and 300U, a dummy plate 400, and a molding structure 500.

In the present specification, as shown in FIG. 1B, a direction parallel to a bottom surface 400a of the dummy plate 400 may be defined as a first direction D1. The bottom surface 400a of the dummy plate 400 may correspond to a surface of a second dummy substrate 410 to be described below. A direction which is parallel to the bottom surface 400a of the dummy plate 400 and intersects the first direction D1 may be defined as a second direction D2. A direction perpendicular to the bottom surface 400a of the dummy plate 400 may be defined as a third direction D3.

Referring to FIGS. 1A and 2, the first semiconductor chip 100 may correspond to a lower portion of the semiconductor package 10. In the present specification, the first semiconductor chip 100 may also be referred to as a logic die, a logic chip, a base die, a buffer chip, a buffer die, or a memory controller. The first semiconductor chip 100 may perform functions of a logic chip, which increase efficiency of data transmission and reduce power consumption. The first semiconductor chip 100 may include a first semiconductor substrate 110, a first upper insulating layer 131, a first upper bonding pad 132, a first through-electrode 150, a first integrated circuit 140, a first interconnection layer 120, and a connection terminal 180.

The first semiconductor substrate 110 may include a semiconductor material such as silicon and/or germanium. The first semiconductor substrate 110 may include a first bottom surface 110a and a first top surface 110b, which are opposite to each other.

The first interconnection layer 120 may be disposed on the first bottom surface 110a of the first semiconductor substrate 110. The first interconnection layer 120 may include a first lower insulating layer 121, a first lower interconnection pattern 123, and a under bump pattern 122. For example, the first lower insulating layer 121 may include at least one from among silicon oxide (SiO₂), silicon nitride (Si₃N₄), and silicon oxynitride (SiOₓN_{y}). The first lower insulating layer 121 may include a plurality of insulating layers. The first lower interconnection pattern 123 may include a plurality of interconnection lines and vias connected thereto. The under bump pattern 122 may be located in a lower portion of the first interconnection layer 120. One surface of the under bump pattern 122 may be connected to the first lower interconnection pattern 123, and another surface of the under bump pattern 122 may be exposed from the first lower insulating layer 121. The connection terminal 180 may be disposed on the exposed surface of the under bump pattern 122. For example, the connection terminal 180 may be a solder ball, a bump, or a pillar.

The first upper insulating layer 131 and the first upper bonding pad 132 may be disposed on the first top surface 110b. For example, the first upper insulating layer 131 may include at least one from among silicon oxide (SiO₂), silicon nitride (Si₃N₄), and silicon oxynitride (SiOₓN_{y}). The first upper bonding pad 132 may be disposed in the first upper insulating layer 131. In certain embodiments, the first upper insulating layer 131 may extend between the first upper bonding pad 132 and the first top surface 110b of the first semiconductor substrate 110.

The first through-electrode 150 may penetrate the first semiconductor substrate 110. For example, the first through-electrode 150 may include a conductive material such as copper. A diffusion barrier pattern (e.g., tantalum nitride (TaN), tantalum (Ta), titanium nitride (TiN), and/or tungsten (W)) may be disposed between the first through-electrode 150 and the first semiconductor substrate 110. One end of the first through-electrode 150 may be connected to the first upper bonding pad 132, and another end of the first through-electrode 150 may be connected to the first lower interconnection pattern 123.

The dummy die 200 may be disposed on the first semiconductor chip 100. The dummy die 200 may not include an integrated circuit and an interconnection pattern, unlike the first semiconductor chip 100. The dummy die 200 may include a first dummy substrate 210, a lower connection insulating layer 221, an upper connection insulating layer 231, an upper dummy bonding pad 232, and dummy through-electrodes 250.

The first dummy substrate 210 may have a first surface 210a and a second surface 210b, which are opposite to each other. The second surface 210b may be bent more than the first surface 210a. In other words, the first surface 210a may be flatter than the second surface 210b. A thickness 210H of the first dummy substrate 210 may change towards the first direction D1 and/or the second direction D2. In other words, the first dummy substrate 210 may include a first region and a second region, which have different thicknesses, and the thickness of the first region may be greater than the thickness of the second region. A difference in thickness between the first region and the second region may be 0.3 μm or more. A magnitude of a height change, in the first direction D1, of the second surface 210b of the first dummy substrate 210 may be greater than a magnitude of a height change, in the first direction D1, of the first surface 210a.

The lower connection insulating layer 221 may be disposed on the first surface 210a, and the upper connection insulating layer 231 may be disposed on the second surface 210b. For example, each of the upper connection insulating layer 231 and the lower connection insulating layer 221 may include at least one from among silicon oxide (SiO₂), silicon nitride (Si₃N₄), and silicon oxynitride (SiOₓN_{y}). The lower connection insulating layer 221 of the dummy die 200 may be in contact with the first upper insulating layer 131 of the first semiconductor chip 100. In some embodiments, the lower connection insulating layer 221 and the first upper insulating layer 131 may be observed as a single insulating layer without an interface therebetween.

The dummy through-electrodes 250 may include a first dummy through-electrode 251 and a second dummy through-electrode 252. The first dummy through-electrode 251 and the second dummy through-electrode 252 may penetrate the first dummy substrate 210. The first dummy through-electrode 251 and the second dummy through-electrode 252 may electrically connect the first semiconductor chip 100 to the second semiconductor chip 300. One end of the first dummy through-electrode 251 and one end of the second dummy through-electrode 252 may be in contact with respective ones of the upper dummy bonding pad 232. Another end of the first dummy through-electrode 251 and another end of the second dummy through-electrode 252 may be in contact with respective ones of the first upper bonding pad 132 of the first semiconductor chip 100. The first dummy through-electrode 251 may have a first height 251H in the third direction D3, and the second dummy through-electrode 252 may have a second height 252H in the third direction D3. The first height 251H may be greater than the second height 252H. For example, a difference between the first height 251H and the second height 252H may range from 0.3 μm to 5 μm. For example, the difference between the first height 251H and the second height 252H may be 2 μm.

A level of a top surface of the first dummy through-electrode 251 may be higher than a level of a top surface of the second dummy through-electrode 252. A level of a bottom surface of the first dummy through-electrode 251 may be substantially the same as a level of a bottom surface of the second dummy through-electrode 252.

For example, the dummy through-electrodes 250 may include a conductive material such as copper. A diffusion barrier pattern (e.g., tantalum nitride (TaN), etc.) may be disposed between each of the dummy through-electrodes 250 and the first dummy substrate 210. The plurality of the upper dummy bonding pad 232 may be disposed on the second surface 210b of the first dummy substrate 210. The plurality of the upper dummy bonding pad 232 may be disposed at different levels by a level difference due to the bent shape of the second surface 210b. In certain embodiments, the upper connection insulating layer 231 may extend between the upper dummy bonding pad 232 and the second surface 210b of the first dummy substrate 210.

A lowermost second semiconductor chip 300B from among the second semiconductor chips 300B, 300 and 300U may be connected to the dummy die 200 by direct contact of bonding pads. Each of the second semiconductor chips 300B, 300 and 300U may be a memory chip. For example, each of the second semiconductor chips 300B, 300 and 300U may be a dynamic random-access memory (DRAM) chip, a static random-access memory (SRAM) chip, or a NAND-FLASH chip. The second semiconductor chips 300B, 300 and 300U may be the same kind of semiconductor chips having the same second integrated circuit 340. In the present specification, each of the second semiconductor chips 300B, 300 and 300U may be referred to as a core die or a core chip.

Each of the second semiconductor chips 300B, 300 and 300U may include a second semiconductor substrate 310, a second upper insulating layer 331, a second upper bonding pad 332, a second through-electrode 350, a second integrated circuit 340, and a second interconnection layer 320.

The second semiconductor substrate 310 may include a semiconductor material such as silicon (Si). The second semiconductor substrate 310 may include a second bottom surface 310a and a second top surface 310b, which are opposite to each other. A thickness of the second semiconductor substrate 310 in the third direction D3 may be substantially uniform along the first direction D1 and/or the second direction D2.

The second bottom surface 310a and the second top surface 310b of the second semiconductor substrate 310 may be bent. A topology of each of the second bottom surface 310a and the second top surface 310b may have a shape which is bent up and down. The topology may represent a connection relationship (e.g., a shape, a structure, etc.) of a surface, and a height of the surface may be checked by the topology.

The second interconnection layer 320 may be disposed on the second bottom surface 310a of the second semiconductor substrate 310. The second interconnection layer 320 may include a second lower insulating layer 321, a second lower interconnection pattern 323, and a lower bonding pad 322. For example, the second lower insulating layer 321 may include at least one from among silicon oxide (SiO₂), silicon nitride (Si₃N₄), and silicon oxynitride (SiOₓN_{y}). The second lower insulating layer 321 may include a plurality of insulating layers. The second lower interconnection pattern 323 may include a plurality of interconnection lines and vias connected thereto. The lower bonding pad 322 may be located in a lower portion of the second interconnection layer 320. One surface of the lower bonding pad 322 may be connected to the second lower interconnection pattern 323, and another surface of the lower bonding pad 322 may be in contact with the upper dummy bonding pad 232 of the dummy die 200.

The second semiconductor chips 300B, 300 and 300U may be connected to each other by direct contact of bonding pads, like the connection by the direct contact of the bonding pads of the lowermost second semiconductor chip 300B and the dummy die 200.

The second upper insulating layer 331 and the second upper bonding pad 332 may be disposed on the second top surface 310b. For example, the second upper insulating layer 331 may include at least one from among silicon oxide (SiO₂), silicon nitride (Si₃N₄), and silicon oxynitride (SiOₓN_{y}). The second upper bonding pad 332 may be disposed in the second upper insulating layer 331. In certain embodiments, the second upper insulating layer 331 may extend between the second upper bonding pad 332 and the second top surface 310b of the second semiconductor substrate 310.

The second through-electrode 350 may penetrate the second semiconductor substrate 310. For example, the second through-electrode 350 may include a conductive material such as copper. A diffusion barrier pattern (e.g., tantalum nitride (TaN)) may be disposed between the second through-electrode 350 and the second semiconductor substrate 310. One end of the second through-electrode 350 may be connected to the second upper bonding pad 332, and another end of the second through-electrode 350 may be connected to the second lower interconnection pattern 323. The second through-electrode 350 may have a third height 350H. In some embodiments, the third height 350H of the second through-electrode 350 may be greater than the first height 251H and the second height 252H of the dummy through-electrodes 250 of the dummy die 200.

The molding structure 500 may cover a top surface of the first semiconductor chip 100 and may cover a side surface of the dummy die 200 and side surfaces of the second semiconductor chips 300B, 300 and 300U. The molding structure 500 may include an insulating material such as an epoxy molding compound (EMC). The molding structure 500 may be disposed between the top surface of the first semiconductor chip 100 and the bottom surface of the dummy plate 400.

The dummy plate 400 may be disposed on an uppermost second semiconductor chip 300U of the second semiconductor chips 300B, 300 and 300U. Referring to FIGS. 1A and 3, the dummy plate 400 may include a second dummy substrate 410 and an adhesive insulating layer 420. The second dummy substrate 410 may include a semiconductor material such as silicon and/or germanium. For example, the second dummy substrate 410 may be a silicon substrate. The second dummy substrate 410 may not include devices (e.g., an integrated circuit), interconnection patterns, and through-electrodes. The adhesive insulating layer 420 may be in contact with the second upper insulating layer 331 and the second upper bonding pad 332 of the uppermost second semiconductor chip 300U. For example, the adhesive insulating layer 420 may include at least one from among silicon oxide (SiO₂), silicon nitride (Si₃N₄), and silicon oxynitride (SiOₓN_{y}). A void of several micrometers or more may be observed or not exist between the adhesive insulating layer 420 and the second upper insulating layer 331 and/or between the adhesive insulating layer 420 and the second upper bonding pad 332.

Referring again to FIG. 1A, the first semiconductor chip 100 may have a first width 100W in the first direction D1. The first width 100W may mean a width of the first semiconductor substrate 110 in the first direction D1. The dummy die 200 may have a second width 200W in the first direction D1. The second width 200W may mean a width of the first dummy substrate 210 in the first direction D1. Each of the second semiconductor chips 300B, 300 and 300U may have a third width 300W in the first direction D1. The third width 300W may mean a width of the second semiconductor substrate 310 in the first direction D1. The dummy plate 400 may have a fourth width 400W in the first direction D1. The fourth width 400W may mean a width of the second dummy substrate 410 in the first direction D1.

The first width 100W and the fourth width 400W may be substantially equal to each other. In the present specification, it may be understood that when widths of components are substantially equal to each other, they may be numerically equal to each other or the components may be designed with the same width and may be manufactured through the same sawing process under the same conditions even though the widths of the components are slightly different from each other. For example, when a difference in width between the components (e.g., the dies and/or the dummy plate) is 10 μm or less, the widths of the components may be substantially equal to each other. The second width 200W and the third width 300W may be substantially equal to each other. The first width 100W and the fourth width 400W may be greater than the second width 200W and the third width 300W.

The first semiconductor chip 100, the dummy die 200, the second semiconductor chip 300B, 300, or 300U and the dummy plate 400 may have a first thickness 100T, a second thickness 200T, a third thickness 300T, and a fourth thickness 400T in the third direction D3, respectively. The fourth thickness 400T may be three times or more greater than each of the first thickness 100T, the second thickness 200T, and the third thickness 300T. For example, the fourth thickness 400T may be 250 μm or more. The first thickness 100T may be equal to or greater than the third thickness 300T. The second thickness 200T may be equal to or less than the third thickness 300T. For example, the third thickness 300T may be 38 μm.

The first thickness 100T may be a distance from the top surface of the first upper insulating layer 131 of the first semiconductor chip 100 to the bottom surface of the first lower insulating layer 121. In addition, the first thickness 100T may be a difference between a level of the top surface of the first upper bonding pad 132 and a level of the bottom surface of the under bump pattern 122. The second thickness 200T may be a sum of a thickness of the upper dummy bonding pad 232 and the first height 251H of the first dummy through-electrode 251, or a sum of the thickness of the upper dummy bonding pad 232 and the second height 252H of the second dummy through-electrode 252. The third thickness 300T may mean a difference between a level of a bottom surface of the lower bonding pad 322 and a level of a top surface of the second upper bonding pad 332. The fourth thickness 400T may mean a sum of a thickness of the second dummy substrate 410 and a thickness of the adhesive insulating layer 420. Alternatively, the fourth thickness 400T may mean the thickness of the second dummy substrate 410.

The upper dummy bonding pad 232 of the dummy die 200 and the lower bonding pad 322 of the second semiconductor chip 300B may be bonded to each other without an interface therebetween so as to be observed as a single structure. However, side surfaces of the upper dummy bonding pad 232 and the lower bonding pad 322 may have different tapered shapes, and thus the levels of the top and bottom surfaces and the thicknesses of the upper dummy bonding pad 232 and the lower bonding pad 322 may be checked using the different tapered shapes to determine the second thickness 200T. The first thickness 100T, the second thickness 200T, the third thickness 300T, and the fourth thickness 400T may be measured using a non-destructive method and/or a destructive method used in the art.

Referring again to FIGS. 1A and 1B, the second semiconductor chips 300U, 300 and 300B may be stacked on the bottom surface 400a of the dummy plate 400 by the direct contact of the bonding pad, and height differences of contact surfaces may sequentially increase as a distance from the dummy plate 400 increases. In other words, a bottom surface 300a8 of the second semiconductor chip 300B closest to the first semiconductor chip 100 may be bent more than a bottom surface 300a1 of the second semiconductor chip 300U closest to the dummy plate 400. This may be because the topology of the contact surfaces may be sequentially transferred and enlarged in processes of bonding the second semiconductor chips 300U, 300 and 300B having thin thicknesses to each other by a hybrid bonding method and bent degrees of the bottom surfaces 300a1 to 300a8 (e.g., contact surfaces) may sequentially increase as the stacking number of the second semiconductor chips 300 increases. According to embodiments of the present disclosure, a top surface 300b1 of the uppermost second semiconductor chip 300U may be flat, and thus a gap may not be generated even though the dummy plate 400 having a thick thickness is used. In other words, a void may be reduced or not occur between the dummy plate 400 and the second semiconductor chip 300U. In addition, the dummy die 200 may be disposed between the lowermost second semiconductor chip 300B and the first semiconductor chip 100, and a bottom surface 200a of the dummy die 200 may be flat. The bottom surface 200a of the dummy die 200 that is flat may be formed by a grinding process as described below, and the bent shape of the surface by accumulation of the topology may be removed. As a result, when the first semiconductor chip 100 comes in direct contact with the bottom surface 200a of the dummy die 200 through the bonding pads, misalignment between the dummy die 200 and the first semiconductor chip 100 may be reduced or not occur.

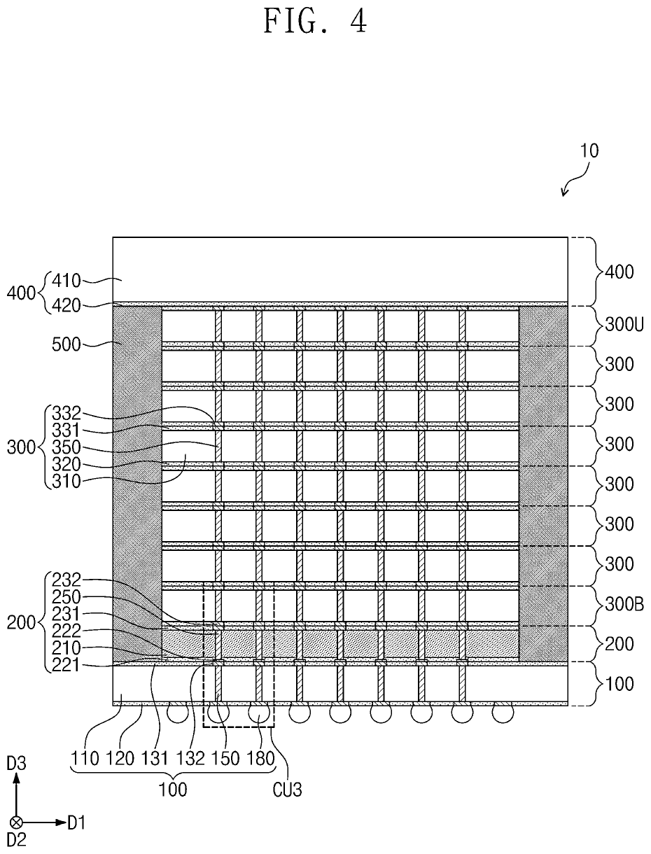

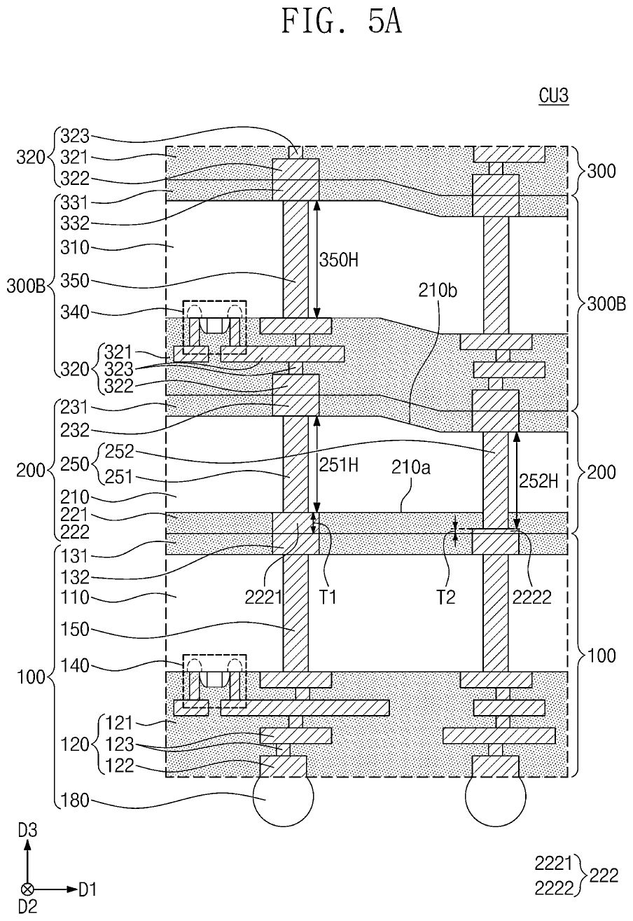

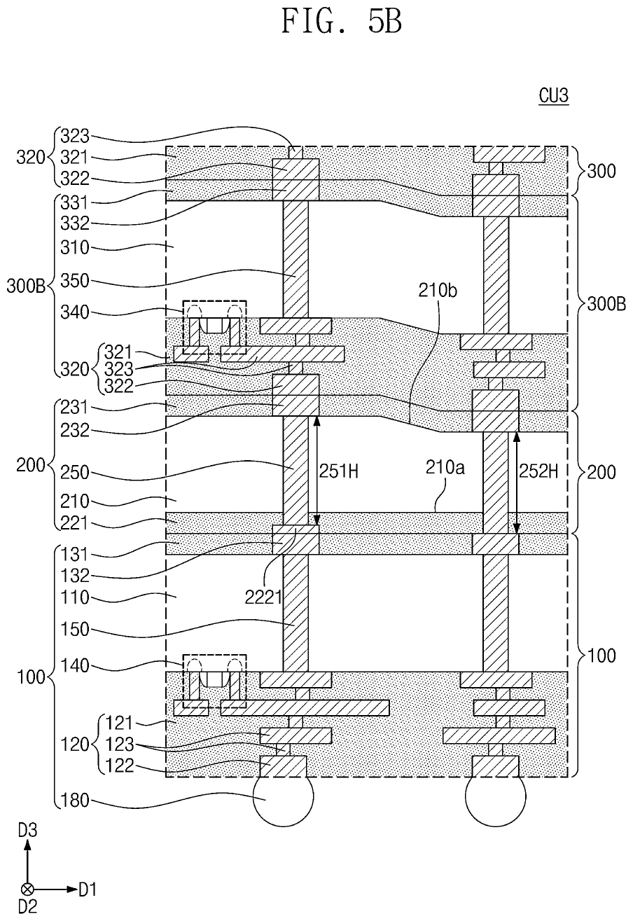

FIG. 4 is a cross-sectional view illustrating a semiconductor package according to some embodiments of the present disclosure. FIG. 5A is an enlarged view corresponding to a region CU3 of FIG. 4. FIG. 5B is an enlarged view corresponding to the region CU3 of FIG. 4. Hereinafter, descriptions of the same features as mentioned above may not be repeated for the purpose of ease and convenience in explanation.

Referring to FIGS. 4 and 5A, a first height 251H of the first dummy through-electrode 251 and a second height 252H of the second dummy through-electrode 252 may be substantially equal to each other. A first lower dummy bonding pad 2221 opposite to the upper dummy bonding pad 232 may be disposed on a bottom surface of the first dummy through-electrode 251. A second lower dummy bonding pad 2222 opposite to the upper dummy bonding pad 232 may be disposed on a bottom surface of the second dummy through-electrode 252. A thickness T2 of the second lower dummy bonding pad 2222 may be less than a thickness T1 of the first lower dummy bonding pad 2221. A level of a bottom surface of the second lower dummy bonding pad 2222 may be substantially the same as a level of a bottom surface of the first lower dummy bonding pad 2221. The second lower dummy bonding pad 2222 and the first lower dummy bonding pad 2221 may be in contact with respective ones of the first upper bonding pad 132.

Referring to FIGS. 4 and 5B, a second height 252H of the second dummy through-electrode 252 may be equal to or less than a first height 251H of the first dummy through-electrode 251. The first lower dummy bonding pad 2221 opposite to the upper dummy bonding pad 232 may be disposed on the bottom surface of the first dummy through-electrode 251. The first lower dummy bonding pad 2221 may be in contact with the first upper bonding pad 132. The second lower dummy bonding pad 2222 opposite to the upper dummy bonding pad 232 may not be disposed on the bottom surface of the second dummy through-electrode 252. In other words, the second dummy through-electrode 252 may be in direct contact with the first upper bonding pad 132 of the first semiconductor chip 100. The level of the bottom surface of the first lower dummy bonding pad 2221 may be substantially the same as a level of the bottom surface of the second dummy through-electrode 252.

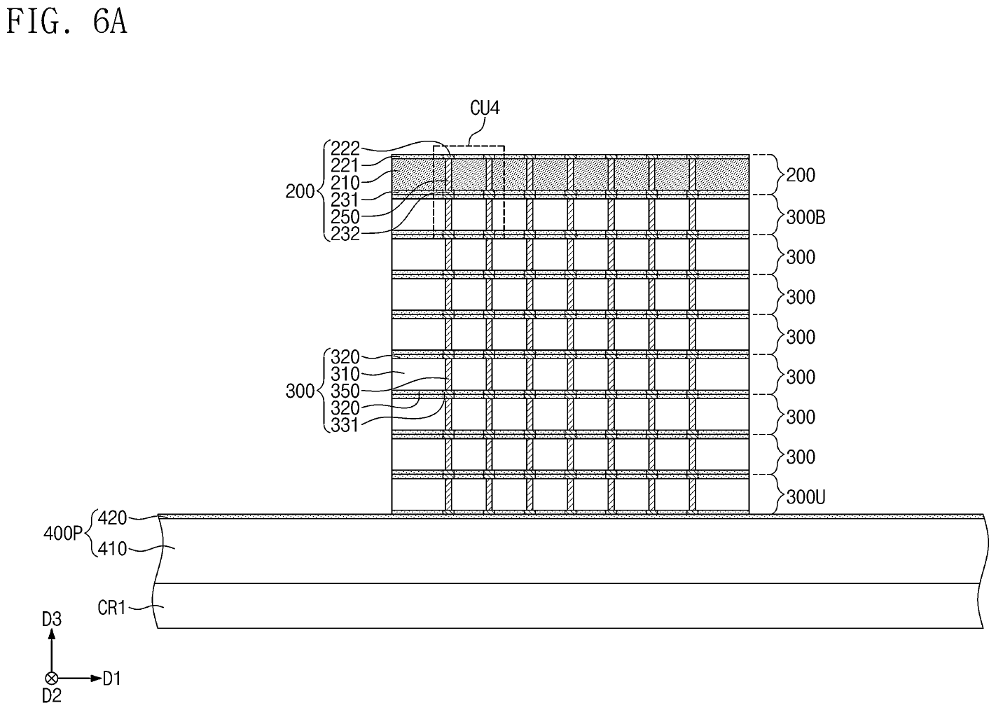

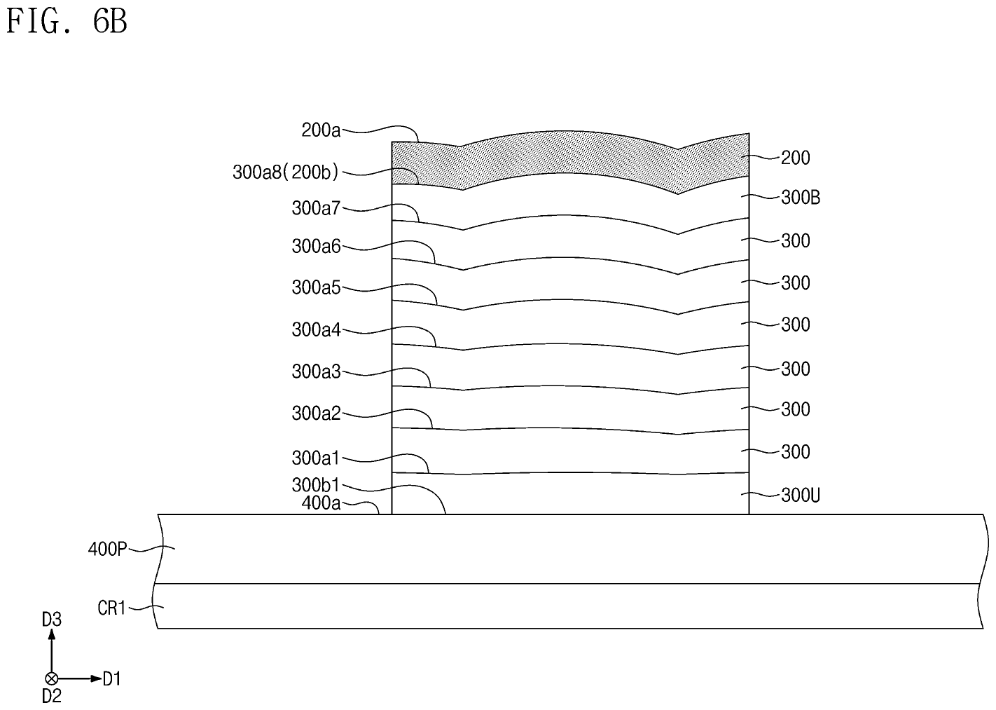

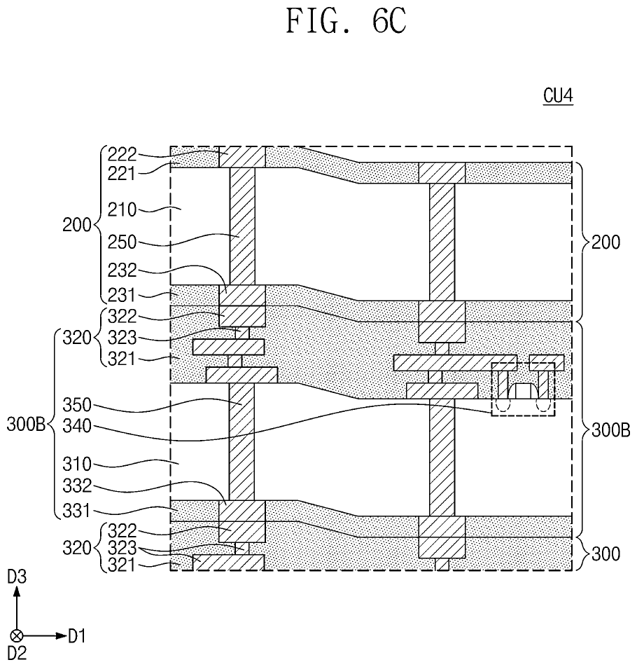

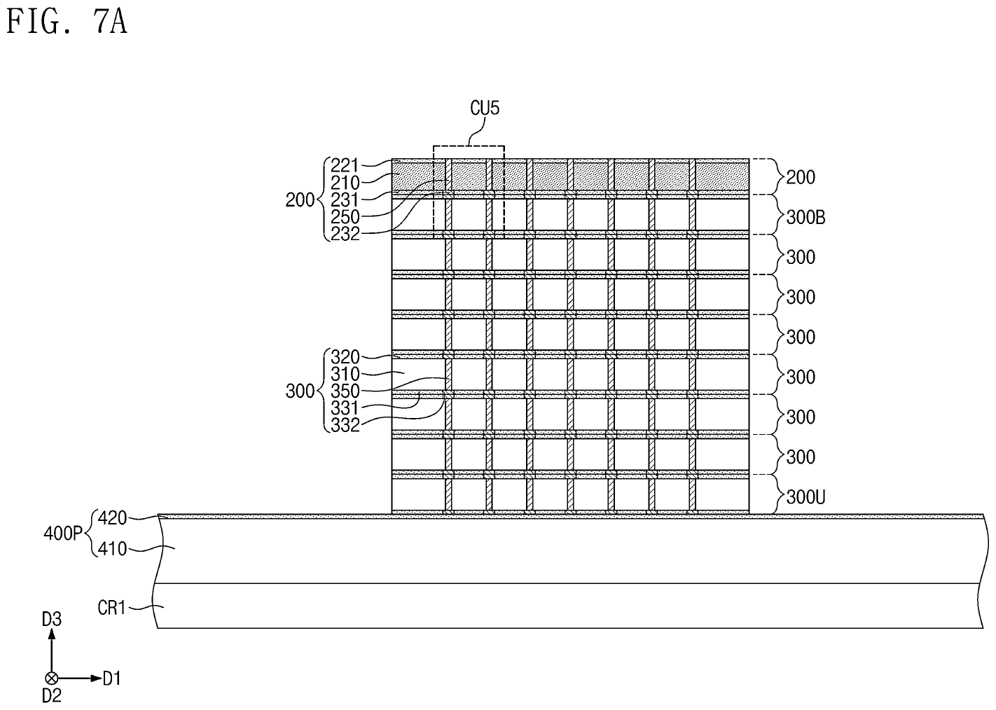

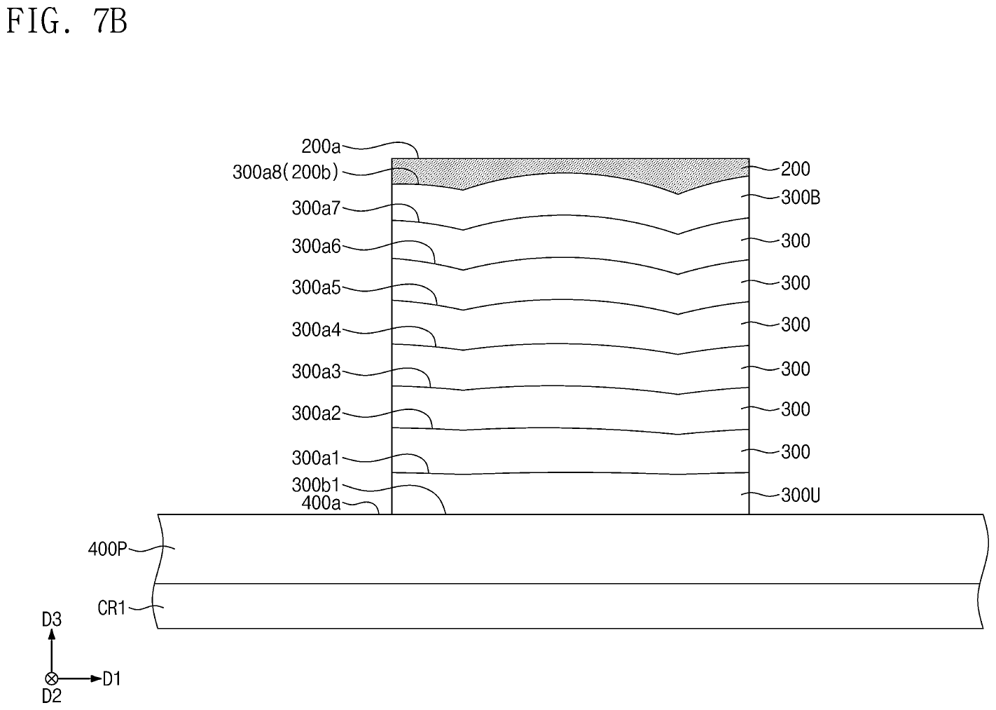

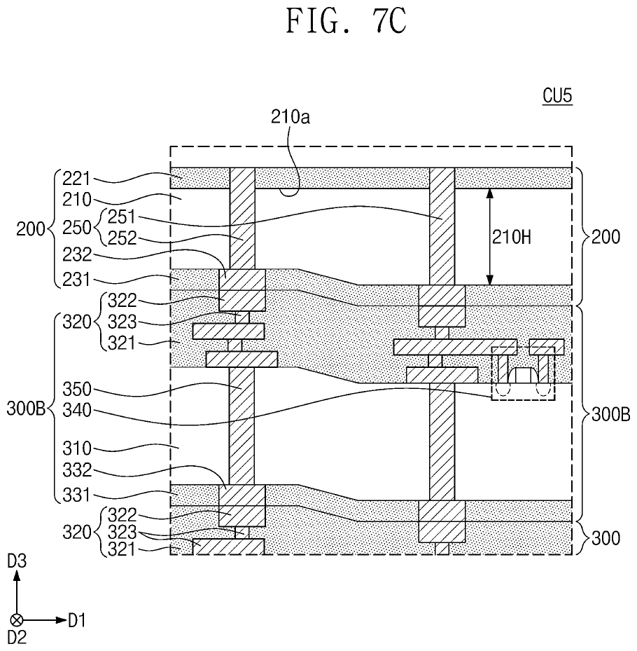

FIGS. 6A, 7A, 8A, and 9A are cross-sectional views illustrating a method of manufacturing a semiconductor package according to some embodiments of the present disclosure. FIGS. 6B, 7B, 8B, and 9B are cross-sectional views conceptually illustrating top surfaces and bottom surfaces of dies of FIGS. 6A, 7A, 8A, and 9A, respectively. FIGS. 6C and 7C are enlarged views of a region CU4 of FIG. 6A and a region CU5 of FIG. 7A, respectively.

Referring to FIGS. 6A, 6B, and 6C, a carrier substrate CR1 may be provided. A preliminary dummy plate 400P may be disposed on the carrier substrate CR1. The preliminary dummy plate 400P may include a second dummy substrate 410 and an adhesive insulating layer 420.

A plurality of second semiconductor chips 300U, 300, and 300B may be sequentially stacked on the preliminary dummy plate 400P. The second semiconductor chip 300U in contact with the preliminary dummy plate 400P may be bonded to the preliminary dummy plate 400P by a hybrid bonding process. The second semiconductor chips 300 adjacent to each other in the third direction D3 may be bonded to each other by the hybrid bonding process. The hybrid bonding process may mean that a copper pad and a copper pad (or silicon oxide and silicon oxide) come in direct contact with each other at a room temperature without a connection terminal (e.g., a bump) and are then bonded to each other at a high temperature by an annealing process when semiconductor chips are bonded to each other. For example, when the second semiconductor chips 300 are bonded to each other, the hybrid bonding process may include a pre-treatment process performed on a top surface of a lower one of the second semiconductor chips 300, a pre-treatment process performed on a bottom surface of an upper one of the second semiconductor chips 300, processes of aligning and compressing the lower and upper second semiconductor chips 300, and a process of bonding the lower and upper second semiconductor chips 300 by using a high temperature and a high pressure.

Referring to FIG. 6B, a top surface (e.g., bottom surface 300a1) of the second semiconductor chip 300U may not be completely flat due to structural features (e.g., metal portions of the second interconnection layer 320, a scribe lane, etc.), and a height variation (or a height difference) may exist at the top surface (e.g., bottom surface 300a1). A bottom surface (e.g., top surface 300b1) of the second semiconductor chip 300U may be flatter than the top surface (e.g., bottom surface 300a1).

In the hybrid bonding process, a bottom surface of the second semiconductor chip 300 in contact with the second semiconductor chip 300U may be deformed to be in contact with the top surface (e.g., bottom surface 300a1) of the second semiconductor chip 300U. A top surface (e.g., bottom surface 300a2) of the second semiconductor chip 300 in contact with the second semiconductor chip 300U may be deformed to have a height variation greater than that of the top surface (e.g., bottom surface 300a1) of the second semiconductor chip 300U. A degree of the deformation may increase as the stacking number of the second semiconductor chips 300 increases.

A dummy die 200 may be disposed on the second semiconductor chip 300B. The dummy die 200 may be bonded to the second semiconductor chip 300B by the hybrid bonding process. A top surface (or exposed surface) (e.g., bottom surface 200a) of the dummy die 200 may be bent. For example, in a case in which the number of the second semiconductor chips 300U, 300, and 300B is 12, a difference in level between the highest place and the lowest place of the exposed surface (e.g., bottom surface 200a) may be 0.3 μm or more. For example, the difference in level between the highest place and the lowest place may be 2 μm. The difference in level may decrease as the number of the second semiconductor chips 300U, 300 and 300B decreases, and the difference in level may increase as the number of the second semiconductor chips 300U, 300 and 300B increases.

Referring to FIGS. 7A, 7B, and 7C, a grinding process may be performed on the exposed surface (e.g., bottom surface 200a) of the dummy die 200. As a result of the grinding process, the pads of the dummy die 200 may be removed, and the dummy through-electrodes 250 may be exposed. In this process, a thickness 210H of the first dummy substrate 210 of the dummy die 200 may be reduced. A reduction of the thickness 210H may be varied depending on a region. As a result, as shown in FIG. 7B, an exposed surface (e.g., bottom surface 200a) of the dummy die 200 may be flatter than a surface 200b opposite thereto. The lower connection insulating layer 221 on a top surface (e.g., first surface 210a) of the first dummy substrate 210 may be removed in the grinding process of the dummy die 200, but a lower connection insulating layer 221 may be generated again by natural oxidation so as to be formed on the top surface (e.g., first surface 210a) of the first dummy substrate 210 that is flat.

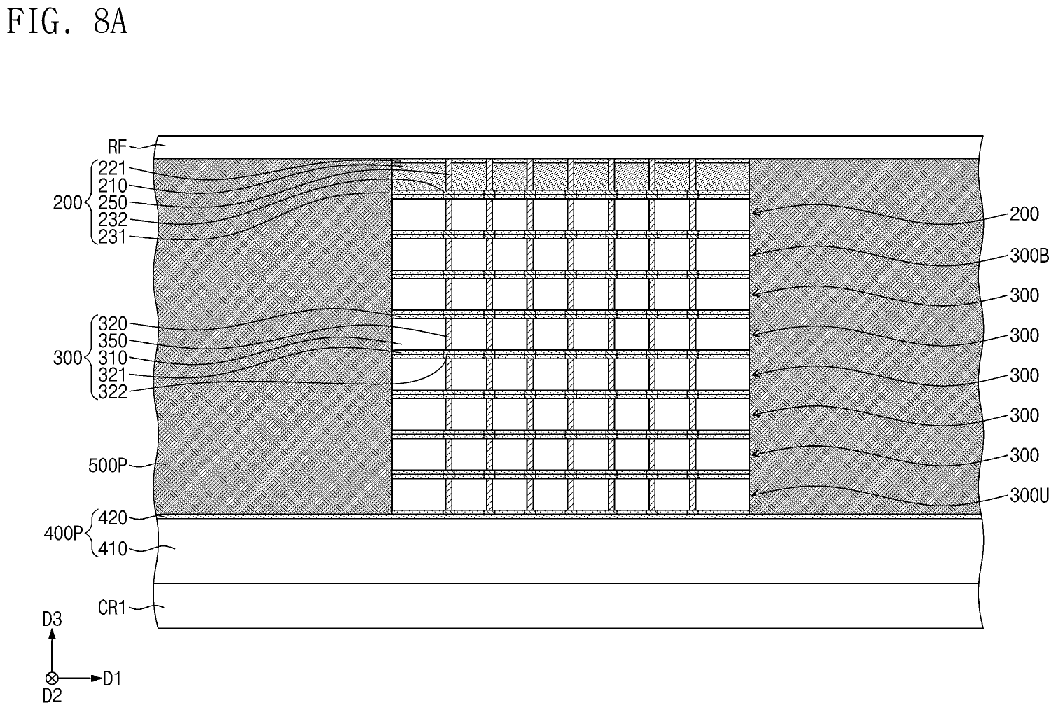

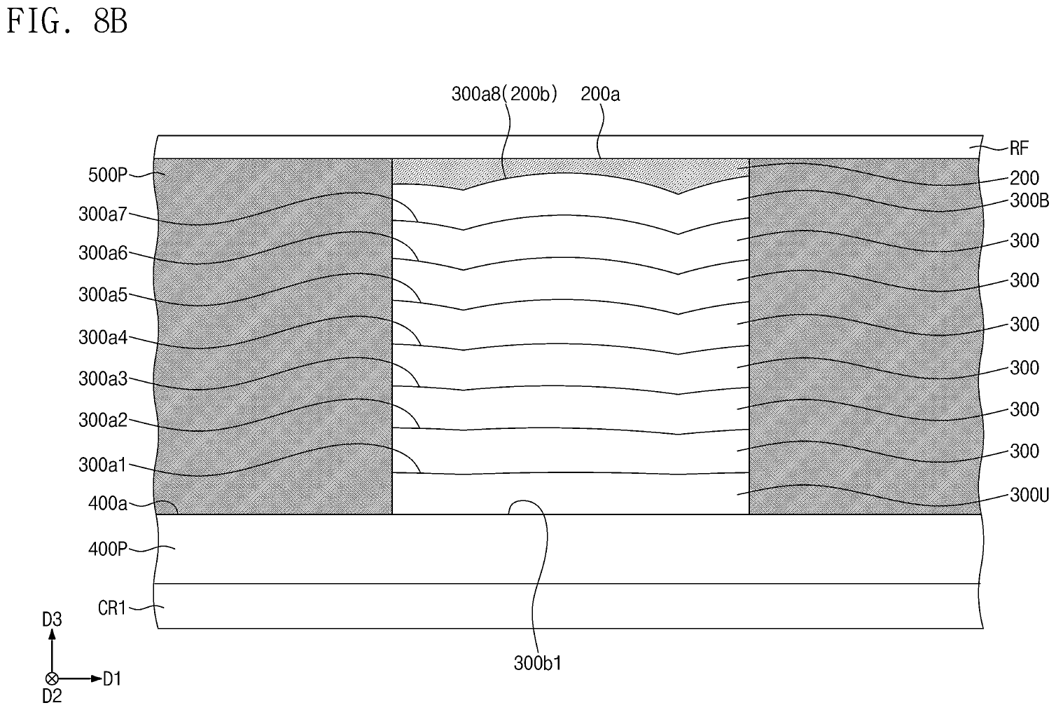

Referring to FIGS. 8A and 8B, a release film RF may be provided on the exposed surface (e.g., bottom surface 200a) of the dummy die 200. Thereafter, a molding layer 500P may be formed to cover a top surface of the preliminary dummy plate 400P, side surfaces of the second semiconductor chips 300U, 300 and 300B, and a side surface of the dummy die 200. The release film RF may protect the exposed surface (e.g., bottom surface 200a) of the dummy die 200, and thus the molding layer 500P may not be formed on the exposed surface (e.g., bottom surface 200a) of the dummy die 200.

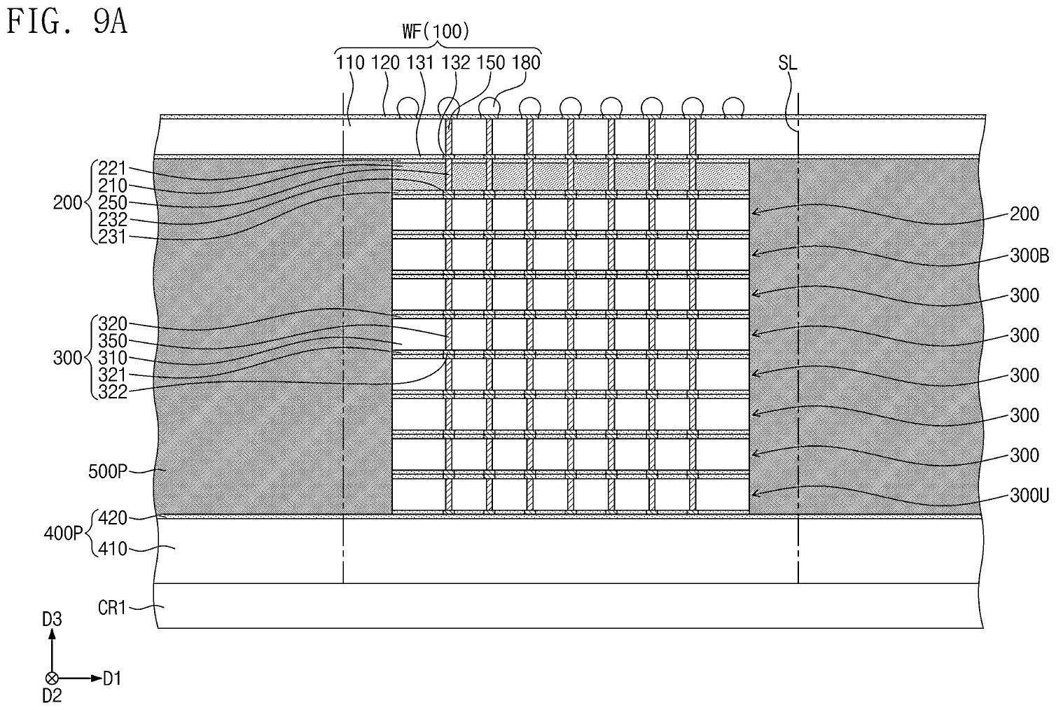

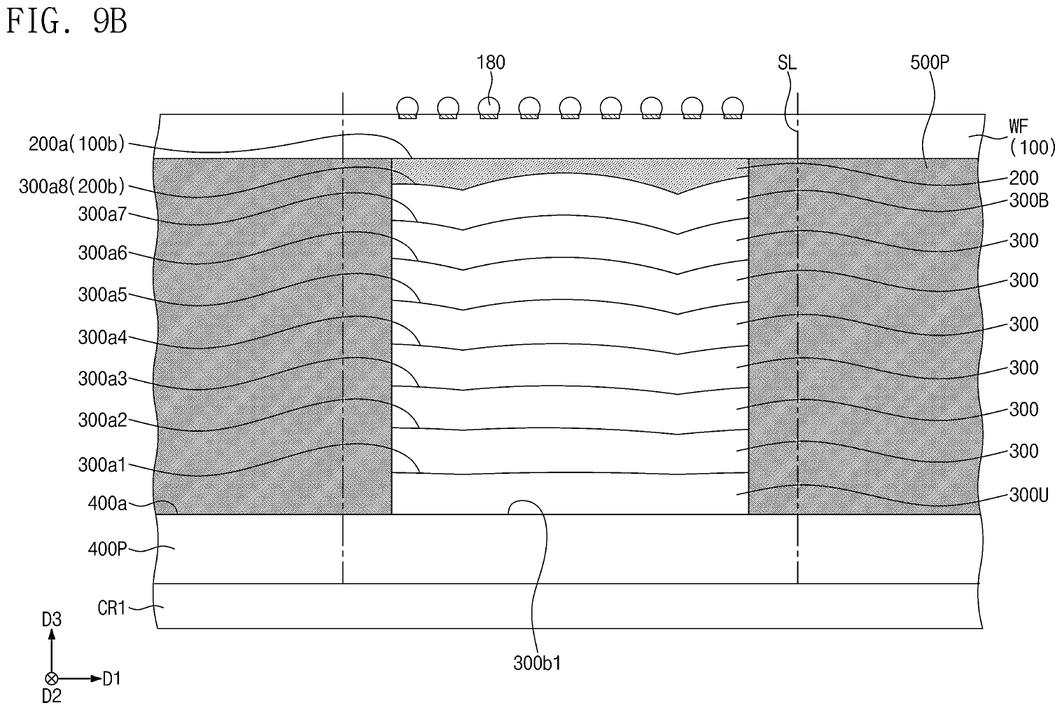

Referring to FIGS. 9A and 9B, the release film RF may be removed, and a wafer WF may be bonded onto the dummy die 200 by a hybrid bonding process. The wafer WF may include portions where a plurality of the first semiconductor chip 100 is formed. Since the exposed surface (e.g., bottom surface 200a) of the dummy die 200 is flat, the wafer WF in contact with the dummy die 200 may not be bent but may be flat in the hybrid bonding process even though the wafer WF has a thin thickness. In addition, the exposed surface (e.g., bottom surface 200a) of the dummy die 200 may be flat to prevent misalignment between the dummy die 200 and the portion of the wafer WF, on which the first semiconductor chip 100 is formed.

Next, a sawing process may be performed on the wafer WF, the molding layer 500P, and the preliminary dummy plate 400P along a sawing line SL to form the first semiconductor chip 100, the molding structure 500, and the dummy plate 400 of FIGS. 1A and 1B. As a result, the semiconductor package 10 of FIGS. 1A and 1B may be manufactured.

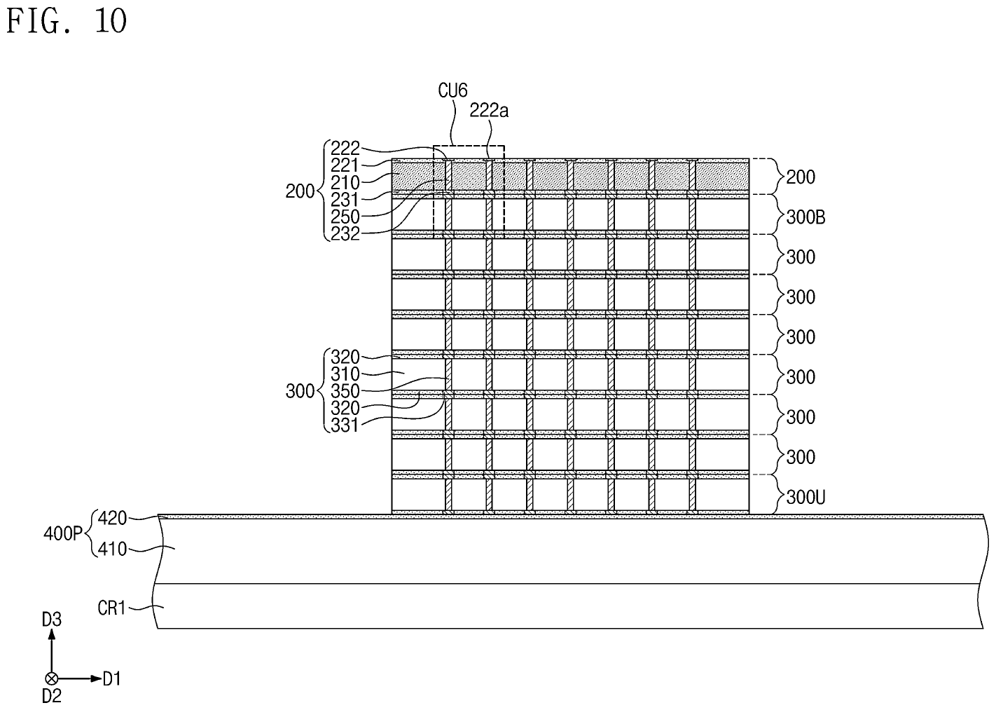

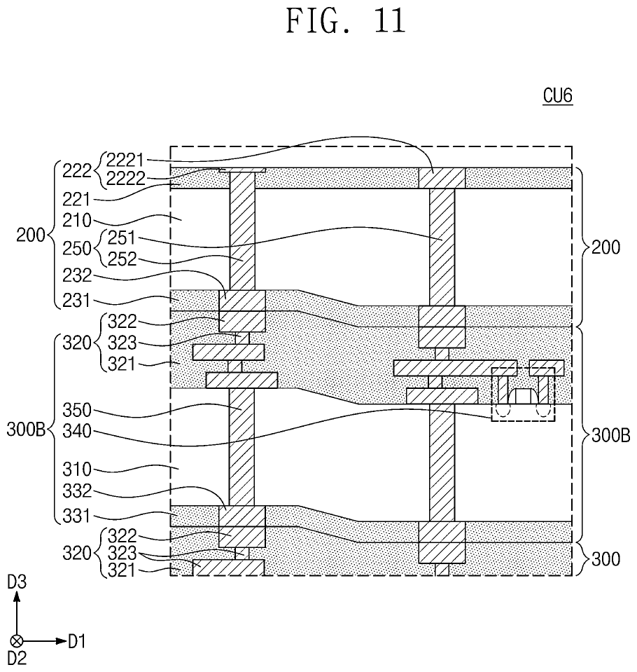

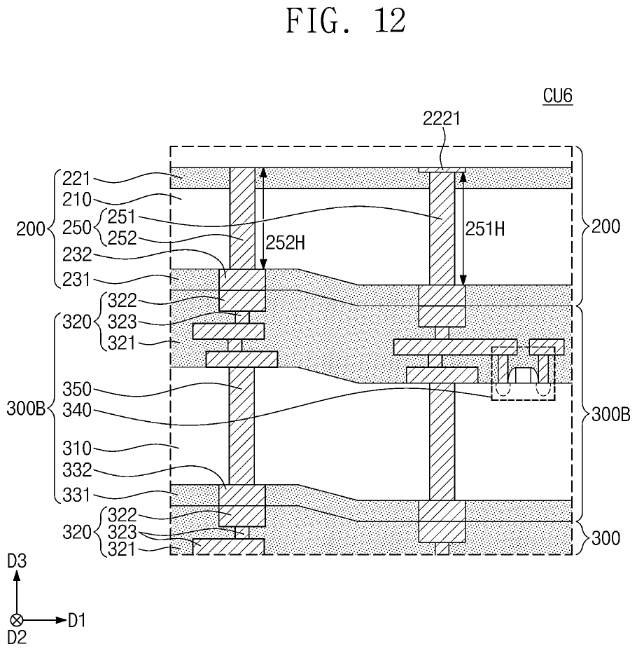

FIG. 10 is a cross-sectional view illustrating a method of manufacturing a semiconductor package according to some embodiments of the present disclosure. FIG. 11 is an enlarged view corresponding to a region CU6 of FIG. 10. FIG. 12 is an enlarged view corresponding to the region CU6 of FIG. 10.

Referring to FIGS. 6A, 6B, and 10, the grinding process may be performed on the exposed surface (e.g., bottom surface 200a) of the dummy die 200. Referring to FIGS. 10 and 11, in the grinding process, thicknesses of lower dummy bonding pads 222 of the dummy die 200 may be reduced, and at least portions of the lower dummy bonding pads 222 may remain. In this process, as shown in FIG. 11, a first lower dummy bonding pad 2221 and a second lower dummy bonding pad 2222 which have different thicknesses may be formed. Next, the same subsequent processes as described with reference to FIGS. 8A and 9A may be performed to manufacture the semiconductor package of FIGS. 4 and 5A.

Alternatively, as shown in FIG. 12, in the grinding process, the second lower dummy bonding pad 2222 of the dummy die 200 may be removed, a thickness of the first lower dummy bonding pad 2221 may be reduced, and a portion of the first lower dummy bonding pad 2221 may remain. In this process, a thickness of the second dummy through-electrode 252 may also be reduced. Next, the same subsequent processes as described with reference to FIGS. 8A and 9A may be performed to manufacture the semiconductor package of FIGS. 4 and 5B.

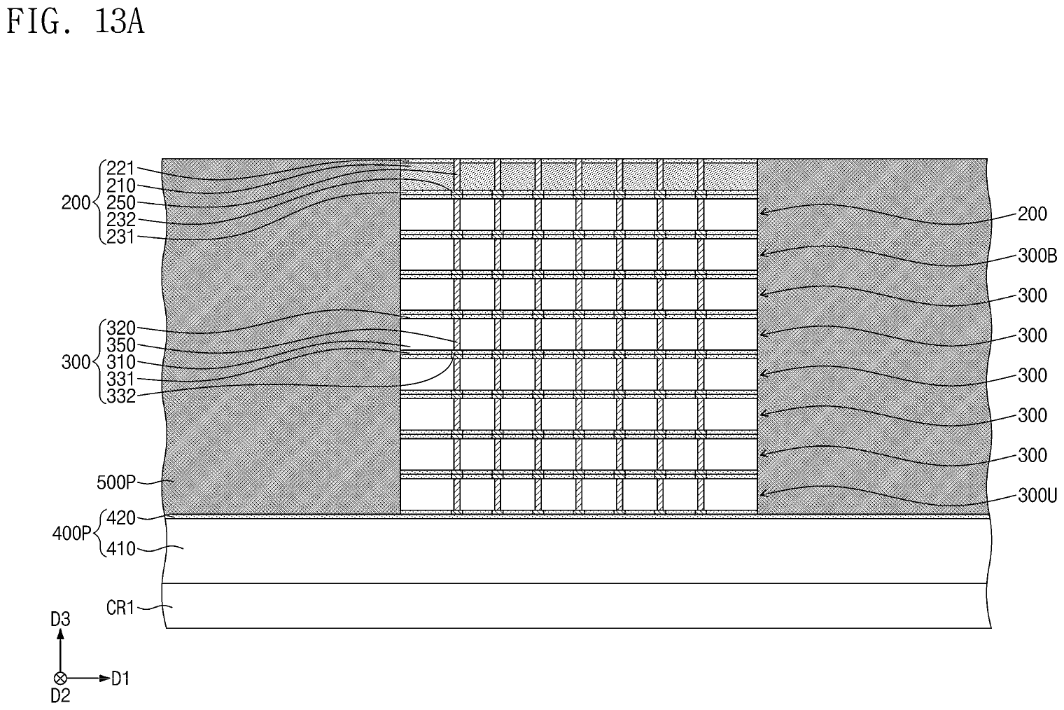

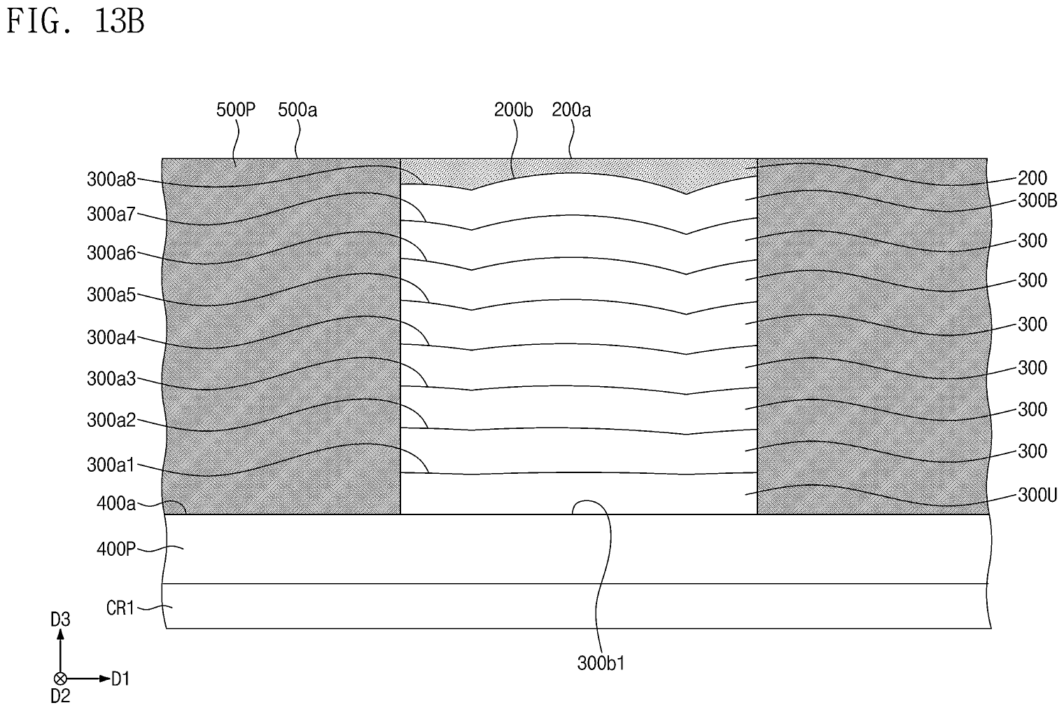

FIG. 13A is a cross-sectional view illustrating a method of manufacturing a semiconductor package according to some embodiments of the present disclosure. FIG. 13B is a cross-sectional view conceptually illustrating top surfaces and bottom surfaces of dies of FIG. 13A.

Referring to FIGS. 6A, 13A, and 13B, a molding layer 500P may be formed to cover the top surface (e.g., bottom surface) 200a of the dummy die 200, the side surface of the dummy die 200, the side surfaces of the second semiconductor chips 300B, 300, and 300U, and the top surface (e.g., bottom surface 400a) of the preliminary dummy plate 400P. A grinding process may be performed to expose the top surface (e.g., bottom surface 200a) of the dummy die 200 from the molding layer 500P. As a result of the grinding process, the top surface (e.g., bottom surface 200a) of the dummy die 200 may be flat, and the top surface (e.g., bottom surface 200a) of the dummy die 200 may be coplanar with a top surface 500a of the molding layer 500P. As a result of the grinding process, the dummy through-electrodes 250 of at least a portion of the dummy die 200 may be exposed (see FIG. 7C). Alternatively, thicknesses of the lower dummy bonding pads 222 of at least a portion of the dummy die 200 may be reduced, and portions of the lower dummy bonding pads 222 may remain (see FIGS. 11 and 12). The same subsequent processes as described with reference to FIG. 9A may be performed to manufacture the semiconductor package of FIG. 1A or 4.

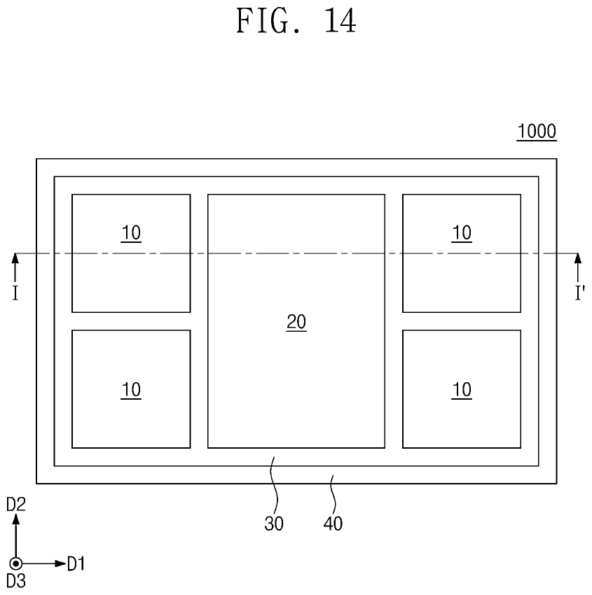

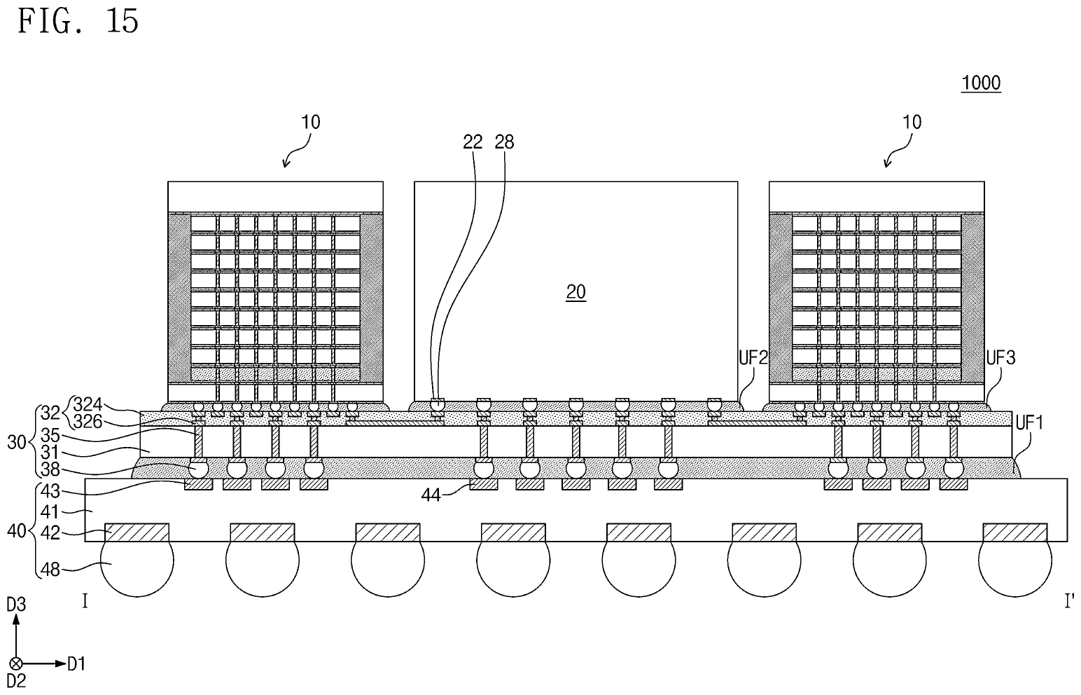

FIG. 14 is a plan view illustrating a semiconductor package according to some embodiments of the present disclosure. FIG. 15 is a cross-sectional view taken along a line I-I′ of FIG. 14. To clearly show components, some components of FIG. 15 are omitted in FIG. 14. Hereinafter, descriptions of the same features as mentioned above may not be repeated for the purpose of ease and convenience in explanation.

Referring to FIGS. 14 and 15, a semiconductor package 1000 according to some embodiments of the present disclosure may include a package substrate 40, an interposer 30, a third semiconductor chip 20, a plurality of semiconductor packages 10 (e.g., chip stack structures), and underfill patterns (e.g., a first underfill pattern UF1, a second underfill pattern UF2, and a third underfill pattern UF3). The semiconductor packages 10 of FIGS. 14 and 15 may each correspond to a respective semiconductor package 10 according to the embodiments described above with reference to FIGS. 1A and 4.

For example, the package substrate 40 may be a printed circuit board (PCB). The package substrate 40 may include lower metal pads 42, first upper metal pads 43, second upper metal pads 44, metal lines, and external connection terminals 48. The first upper metal pads 43 and the second upper metal pads 44 may be disposed in an upper portion of the package substrate 40, and the lower metal pads 42 may be disposed in a lower portion of the package substrate 40. The first upper metal pads 43 may overlap with the semiconductor packages 10 in the third direction D3. The second upper metal pads 44 may overlap with the third semiconductor chip 20 in the third direction D3. The first upper metal pads 43 and the second upper metal pads 44 may be in contact with first connection terminals 38 to be described below, respectively. The metal lines may connect the first upper metal pads 43 and the second upper metal pads 44 to the lower metal pads 42. The external connection terminals 48 may be disposed on the lower metal pads 42, respectively. The external connection terminals 48 may include a conductive material such as solder.

The interposer 30 may be disposed on the package substrate 40. The interposer 30 may include a fourth semiconductor substrate 31, fourth through-electrodes 35, an interconnection layer 32, and the first connection terminals 38. The fourth semiconductor substrate 31 may include a semiconductor material such as silicon and/or germanium and may be, for example, a silicon substrate. The interconnection layer 32 may be disposed on the fourth semiconductor substrate 31. The interconnection layer 32 may include an insulating layer 324 and an interconnection structure 326 in the insulating layer 324. The insulating layer 324 may be an insulating layer such as a silicon oxide layer. The insulating layer 324 is illustrated as a single layer but may include a plurality of insulating layers in certain embodiments. The interconnection structure 326 may electrically connect the third semiconductor chip 20 to at least one the semiconductor packages 10. Each of the fourth through-electrodes 35 may penetrate the fourth semiconductor substrate 31 so as to be connected to the first connection terminals 38 through, for example, a pad.

A first underfill pattern UF1 may be disposed between the interposer 30 and the package substrate 40. For example, the first underfill pattern UF1 may include an epoxy resin composite. The first underfill pattern UF1 may fill a space between the first connection terminals 38.

The third semiconductor chip 20 and the plurality of semiconductor packages 10 may be disposed on the interposer 30. For example, the third semiconductor chip 20 may be located on a central portion of the interposer 30. The semiconductor packages 10 may be spaced apart from each other in the first direction D1 with the third semiconductor chip 20 interposed therebetween. As shown in FIG. 14, two semiconductor packages 10 may be disposed adjacent to one side surface of the third semiconductor chip 20, and two semiconductor packages 10 may be disposed adjacent to another side surface of the third semiconductor chip 20. Adjacent semiconductor packages 10 may be spaced apart from each other in the second direction D2.

In certain embodiments, three semiconductor packages 10 may be disposed adjacent to one side surface of the third semiconductor chip 20, and three semiconductor packages 10 may be disposed adjacent to another side surface of the third semiconductor chip 20. In certain embodiments, the semiconductor packages 10 may be variously disposed.

The third semiconductor chip 20 may be a logic chip. For example, the third semiconductor chip 20 may be a central processing unit (CPU), a graphics processing unit (GPU), or an application specific integrated circuit (ASIC). The third semiconductor chip 20 may be configured to transmit signals to the semiconductor packages 10 and/or to receive signals from the semiconductor packages 10. The third semiconductor chip 20 may include chip pads 22 disposed in its lower portion. Second connection terminals 28 may be disposed on the chip pads 22, respectively. The second connection terminals 28 may include a conductive material such as solder.

The second connection terminals 28 of the third semiconductor chip 20 and the connection terminals 180 of the semiconductor packages 10 may be in contact with pads of a top surface of the interposer 30. A second underfill pattern UF2 may be disposed between the third semiconductor chip 20 and the interposer 30. The second underfill pattern UF2 may fill a space between the second connection terminals 28. A third underfill pattern UF3 may be disposed between the semiconductor packages 10 and the interposer 30. The third underfill pattern UF3 may fill a space between the connection terminals 180. For example, the second underfill pattern UF2 and the third underfill pattern UF3 may include an epoxy resin composite.

According to embodiments of the present disclosure, the core dies may be sequentially stacked on the dummy plate. As a result, even though the thickness of the dummy plate increases, occurrence of a void between the dummy plate and the core die may be reduced when the dummy plate is bonded to the core die, and thus adhesive strength between the dummy plate and the core die may be improved. In addition, the thickness of the dummy plate may be increased to improve a heat dissipation effect. The dummy die may be disposed between the buffer die and the core die, and a surface of the dummy die, which is in contact with the buffer die, may be flat. As a result, the misalignment between the buffer die and the dummy die may be reduced, and thus the dummy die may smoothly electrically connect the buffer die to the core dies. Reliability of the semiconductor package may be improved by the above features.

While non-limiting example embodiments of the present disclosure have been particularly shown and described, it will be understood by one of ordinary skill in the art that variations in form and detail may be made therein without departing from the spirit and scope of the present disclosure.

What is claimed is:

1. A semiconductor package comprising:
a first semiconductor chip;
a dummy die on the first semiconductor chip;
second semiconductor chips stacked on the dummy die; and
a dummy plate on the second semiconductor chips,
wherein each of the first semiconductor chip, the dummy die, and the second semiconductor chips comprises through-electrodes,
wherein the dummy die and a lowermost one among the second semiconductor chips, closest to the dummy die, are connected to each other by direct contact of first bonding pads,
wherein adjacent ones of the second semiconductor chips are connected to each other by direct contact of second bonding pads,
wherein the first semiconductor chip, the dummy die, the second semiconductor chips and the dummy plate have a first width, a second width, a third width, and a fourth width in a horizontal direction, respectively, and
wherein the fourth width is greater than the second width and the third width.

2. The semiconductor package of claim 1, wherein the first width is substantially equal to the fourth width.

3. The semiconductor package of claim 1, wherein the second width is substantially equal to the third width.

4. The semiconductor package of claim 1, wherein the dummy die does not comprise an integrated circuit and an interconnection pattern.

5. The semiconductor package of claim 1, wherein the dummy die comprises a semiconductor substrate,
wherein a direction parallel to a top surface of the semiconductor substrate is defined as a first direction,
wherein a direction perpendicular to the top surface of the semiconductor substrate is defined as a second direction,
wherein a magnitude of a height change, in the second direction, of the top surface of the semiconductor substrate toward the first direction is greater than a magnitude of a height change, in the second direction, of a bottom surface of the semiconductor substrate toward the first direction, and
wherein the top surface is farther than the bottom surface from the first semiconductor chip.

6. The semiconductor package of claim 1, wherein the dummy die comprises a semiconductor substrate,
wherein the semiconductor substrate comprises a first region and a second region, and
wherein a thickness of the first region and a thickness of the second region is different from each other by 0.3 μm or more.

7. The semiconductor package of claim 1, wherein the first semiconductor chip has a first thickness,
wherein the dummy die has a second thickness,
wherein each of the second semiconductor chips has a third thickness,
wherein the dummy plate has a fourth thickness, and
wherein the fourth thickness is three times or more greater than each of the first thickness, the second thickness, and the third thickness.

8. The semiconductor package of claim 7, wherein the first thickness is greater than the second thickness and the third thickness.

9. The semiconductor package of claim 7, wherein the second thickness is less than the third thickness.

10. The semiconductor package of claim 1, wherein the through-electrodes of the dummy die comprise:
a first dummy through-electrode having a first height; and
a second dummy through-electrode laterally spaced apart from the first dummy through-electrode and having a second height, and
wherein the first height is greater than the second height.

11. The semiconductor package of claim 1, wherein the through-electrodes of the dummy die comprise:
a first dummy through-electrode; and
a second dummy through-electrode laterally spaced apart from the first dummy through-electrode,
wherein a level of a top surface of the first dummy through-electrode is higher than a level of a top surface of the second dummy through-electrode, and
wherein a bottom surface of the first dummy through-electrode has substantially the same height as a height of a bottom surface of the second dummy through-electrode.

12. The semiconductor package of claim 1, wherein the dummy die comprises:
a first dummy through-electrode;
a second dummy through-electrode laterally spaced apart from the first dummy through-electrode;
a first bonding pad on a bottom surface of the first dummy through-electrode; and
a second bonding pad on a bottom surface of the second dummy through-electrode,
wherein a first thickness of the first bonding pad is greater than a second thickness of the second bonding pad.

13. The semiconductor package of claim 12, wherein a first height of the first dummy through-electrode is substantially equal to a second height of the second dummy through-electrode.

14. The semiconductor package of claim 1, wherein the dummy die comprises:
a first dummy through-electrode;
a second dummy through-electrode laterally spaced apart from the first dummy through-electrode; and
a first bonding pad on a bottom surface of the first dummy through-electrode,
wherein a level of a bottom surface of the first bonding pad is substantially the same as a level of a bottom surface of the second dummy through-electrode.

15. A semiconductor package comprising:
a first semiconductor chip;
a dummy die on the first semiconductor chip;
second semiconductor chips stacked on the dummy die;
a dummy plate on the second semiconductor chips; and
a molding structure between the first semiconductor chip and the dummy plate,
wherein each of the first semiconductor chip, the dummy die, and the second semiconductor chips comprises through-electrodes,
wherein the dummy die and the first semiconductor chip are connected to each other by direct contact of first bonding pads,
wherein the dummy die and a lowermost one among the second semiconductor chips are connected to each other by direct contact of second bonding pads,
wherein adjacent ones of the second semiconductor chips are connected to each other by direct contact of third bonding pads,
wherein the dummy plate and an uppermost one among the second semiconductor chips are connected to each other by direct contact of insulating materials, and
wherein the molding structure is on a top surface of the first semiconductor chip, a side surface of the dummy die, side surfaces of the second semiconductor chips, and a bottom surface of the dummy plate.

16. The semiconductor package of claim 15, wherein the dummy plate comprises silicon, and
wherein the insulating materials comprises silicon oxide.

17. The semiconductor package of claim 15, wherein the dummy die comprises a semiconductor substrate,
wherein a direction parallel to a top surface of the semiconductor substrate is defined as a first direction,
wherein a direction perpendicular to the top surface of the semiconductor substrate is defined as a second direction,
wherein a magnitude of a height change, in the second direction, of the top surface of the semiconductor substrate toward the first direction is greater than a magnitude of a height change, in the second direction, of a bottom surface of the semiconductor substrate toward the first direction, and
wherein the top surface of the semiconductor substrate is farther than the bottom surface of the semiconductor substrate from the first semiconductor chip.

18. The semiconductor package of claim 15, wherein a thickness of the dummy plate is 250 μm or more.

19. The semiconductor package of claim 15, wherein the through-electrodes of the dummy die comprise:
a first dummy through-electrode having a first height; and
a second dummy through-electrode laterally spaced apart from the first dummy through-electrode and having a second height, and
wherein the first height is greater than the second height.

20. A semiconductor package comprising:
a package substrate;
an interposer on the package substrate;
a logic chip on the interposer; and
chip stack structures spaced apart from each other with the logic chip interposed therebetween,
wherein each of the chip stack structures comprises:
a buffer die;
a dummy die on the buffer die;
core dies stacked on the dummy die;
a dummy plate on the core dies; and
a molding structure between the buffer die and the dummy plate,
wherein each of the buffer die, the dummy die, and the core dies comprises through-electrodes,
wherein the dummy die and the buffer die are connected to each other by direct contact of first bonding pads,
wherein the dummy die and a lowermost one among the core dies are connected to each other by direct contact of second bonding pads,
wherein adjacent ones of the core dies are connected to each other by direct contact of third bonding pads,
wherein the dummy plate and an uppermost one among the core dies are connected to each other by direct contact of insulating materials,
wherein the molding structure is on a top surface of the buffer die, a side surface of the dummy die, side surfaces of the core dies, and a bottom surface of the dummy plate,
wherein the buffer die, the dummy die, the core dies, and the dummy plate have a first width, a second width, a third width, and a fourth width in a horizontal direction, respectively,
wherein the first width is substantially equal to the fourth width, and
wherein the second width is substantially equal to the third width.
